(19) United States
(12) Patent Application Publication
(10) Pub. No.: US 2026/0026125 A1
(43) Pub. Date: Jan. 22, 2026

(54) SEMICONDUCTOR DEVICE AND ELECTRONIC APPARATUS

(71) Applicant: Sony Semiconductor Solutions Corporation, Kanagawa (JP)

(72) Inventor: Yusaku Sugimori, Kanagawa (JP)

(21) Appl. No.: 18/995,046

(22) PCT Filed: Aug. 1, 2023
(86) PCT No.: PCT/JP2023/028064

§ 371 Date: Jan. 15, 2025

(30) Foreign Application Priority Data
Aug. 17, 2022 (JP) 2022-129910

(51) Int. Cl. H10F 39/00

(52) U.S. Cl. CPC H10F 39/809

(57) ABSTRACT

In one example, a semiconductor device includes a first semiconductor, a second semiconductor, and a third semiconductor that are stacked in a vertical direction. The second semiconductor is disposed between the first semiconductor and the third semiconductor and includes a conversion circuit that converts an electrical characteristic or a physical characteristic. The technology can be applied to, for example, solid-state imaging devices or the like.

### TECHNICAL FIELD

The present disclosure relates to a semiconductor device and an electronic apparatus, and more particularly to a semiconductor device and an electronic apparatus capable of reducing manufacturing cost.

### BACKGROUND ART

For the purpose of enhancing functionality of an imaging device, a solid-state imaging device has been proposed in which two semiconductor substrates are joined by CuCu-bonding to a circuit surface on a side opposite to a light incident surface of a first semiconductor substrate on which a photoelectric conversion element is formed. The two semiconductor substrates are: a second semiconductor substrate on which a memory circuit is mounted; and a third semiconductor substrate on which a logic circuit is mounted (see, for example, Patent Document 1).

### CITATION LIST

### Patent Document

Patent Document 1: WO 2019/087764 A

### SUMMARY OF THE INVENTION

### Problems to be Solved by the Invention

For example, in the solid-state imaging device having the stacked structure disclosed in Patent Document 1, in order to reduce manufacturing cost, it is desirable to use a general-purpose semiconductor chip as the second semiconductor substrate or the third semiconductor substrate to be joined to the first semiconductor substrate.

The present disclosure has been made in view of such a situation, and an object of the present disclosure is to reduce manufacturing cost by using a general-purpose semiconductor chip as a semiconductor substrate to be joined.

### Solutions to Problems

In a semiconductor device according to a first aspect of the present disclosure, a first semiconductor, a second semiconductor, and a third semiconductor are stacked in a vertical direction, and the second semiconductor disposed between the first semiconductor and the third semiconductor includes a conversion circuit that converts an electrical characteristic or a physical characteristic.

An electronic apparatus according to a second aspect of the present disclosure includes a semiconductor device in which a first semiconductor, a second semiconductor, and a third semiconductor are stacked in a vertical direction, and the second semiconductor disposed between the first semiconductor and the third semiconductor includes a conversion circuit that converts an electrical characteristic or a physical characteristic.

In the first and second aspects of the present disclosure, a first semiconductor, a second semiconductor, and a third semiconductor are stacked in a vertical direction, and the second semiconductor disposed between the first semiconductor and the third semiconductor includes a conversion circuit that converts an electrical characteristic or a physical characteristic.

The semiconductor device and the electronic apparatus may be independent devices, or modules incorporated in other devices.

### BRIEF DESCRIPTION OF DRAWINGS

FIG. 1 is a cross-sectional view of a first embodiment of an imaging device to which the technology of the present disclosure is applied.

FIG. 2 is a cross-sectional view of a second embodiment of an imaging device to which the technology of the present disclosure is applied.

FIG. 3 is a cross-sectional view of a third embodiment of an imaging device to which the technology of the present disclosure is applied.

FIG. 4 is a cross-sectional view of a fourth embodiment of an imaging device to which the technology of the present disclosure is applied.

FIG. 5 is a cross-sectional view of a fifth embodiment of an imaging device to which the technology of the present disclosure is applied.

FIG. 6 is a block diagram illustrating a configuration example of the imaging device according to the second to fifth embodiments.

FIG. 7 is a diagram for explaining a parallel-serial conversion circuit included in a conversion circuit.

FIG. 8 is a diagram for explaining a serial-parallel conversion circuit included in the conversion circuit.

FIG. 9 is a diagram for explaining a usage example of an image sensor.

FIG. 10 is a block diagram illustrating a configuration example of an imaging device as an electronic apparatus to which the technology of the present disclosure is applied.

FIG. 11 is a block diagram illustrating an example of a schematic configuration of a vehicle control system.

FIG. 12 is an explanatory view illustrating an example of an installation position of an outside-vehicle information detecting section and an imaging section.

### MODE FOR CARRYING OUT THE INVENTION

A mode for carrying out the present technology (hereinafter referred to as an embodiment) will be described below with reference to the accompanying drawings. The description will be given in the following order.
1. First embodiment of imaging device
2. Second embodiment of imaging device
3. Third embodiment of imaging device
4. Fourth embodiment of imaging device
5. Fifth embodiment of imaging device
6. Block diagram of imaging device
7. Specific configuration example of conversion circuit
8. Summary
9. Usage example of imaging device
10. Example of application to electronic apparatus
11. Example applications to mobile objects

Note that, in the drawings referred to in the following description, the same or similar parts are denoted by the same or similar reference signs, and the description thereof will not be repeated as appropriate. The drawings are schematic, and the relationship between the thickness and the plane dimension, the ratio of the thickness of each layer, and other points are different from the actual ones. Furthermore, the drawings may include portions having different dimensional relationships and ratios.

Furthermore, the definitions of directions such as up and down or the like in the following description are merely definitions for convenience of description, and do not limit the technical idea of the present disclosure. For example, when an object is observed by rotating the object by 90°, the up and down are converted into and read as left and right, and when the object is observed by rotating the object by 180°, the up and down are inverted and read.

Hereinafter, embodiments of an imaging device to which the present technology is applied will be described, but the present technology can be applied to general semiconductor devices.

### 1. First Embodiment of Imaging Device

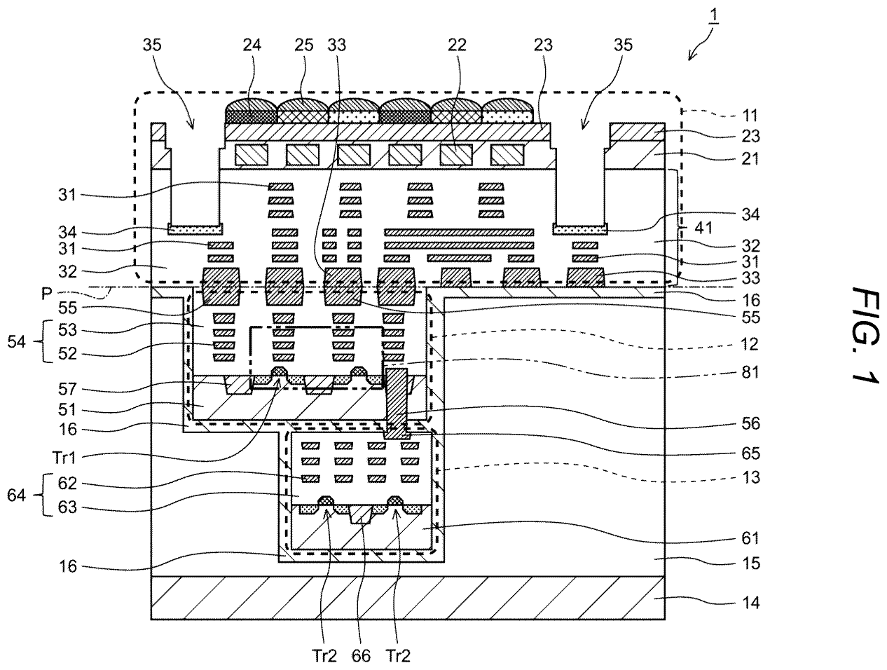

FIG. 1 illustrates a cross-sectional view of a first embodiment of an imaging device to which the present technology is applied.

An imaging device 1 illustrated in FIG. 1 is a CMOS solid-state imaging device in which pixels each including a photoelectric conversion element are arranged in a matrix.

The imaging device 1 has a stacked structure in which a second semiconductor 12 and a third semiconductor 13, which are silicon dies smaller in plane size than a first semiconductor 11 as a main substrate, are directly joined as a sub-substrate to the first semiconductor 11. The first semiconductor 11 to the third semiconductor 13 are stacked in a vertical direction which is a lengthwise direction in the figure, and the second semiconductor 12 is disposed between the first semiconductor 11 and the third semiconductor 13. A one dotted chain line P indicates a junction surface between the first semiconductor 11 and the second semiconductor 12.

The stacked structural object of the first semiconductor 11 to the third semiconductor 13 is connected to a support substrate 14. The first semiconductor 11 has a larger plane size than that of the second semiconductor 12 and the third semiconductor 13. Between the first semiconductor 11 and the support substrate 14, an insulating layer 15 is formed in a region other than the second semiconductor 12 and the third semiconductor 13, and the second semiconductor 12 and the third semiconductor 13 are embedded in the insulating layer 15.

The first semiconductor 11 is a sensor substrate in which a plurality of pixels including photoelectric conversion elements is arranged in a matrix. The second semiconductor 12 is a chip-shaped substrate on which a conversion circuit 81 that converts an electrical characteristic or a physical characteristic is formed, between the first semiconductor 11 and the third semiconductor 13. Details of the conversion circuit 81 will be described later. The third semiconductor 13 is a chip-shaped substrate on which a logic circuit is formed. The logic circuit includes, for example, a signal processing circuit that processes a signal generated in each pixel of the first semiconductor 11, an AI processing circuit that performs AI processing (recognition processing) based on a signal generated in each pixel of the first semiconductor 11, and the like. The third semiconductor 13 may be a chip-shaped substrate on which a memory circuit that stores a signal generated in each pixel of the first semiconductor 11 is formed.

The first semiconductor 11 includes a semiconductor substrate 21 using, for example, silicon (Si) as a semiconductor. On the semiconductor substrate 21, photodiodes 22 as photoelectric conversion elements are formed in pixel units. In the figure, a planarizing film 23 is formed on a light incident surface side of the semiconductor substrate 21, which is an upper side, and a color filter 24 and an on-chip lens 25 are formed for each pixel on the planarizing film 23.

A wiring layer 41 including a plurality of layers of metal wiring lines 31 and an insulating layer 32 is formed on a circuit formation surface side of the semiconductor substrate 21, which is a lower side in the figure, opposite to the light incident surface side. In the example of FIG. 1, the number of layers of the metal wiring lines 31 is 6, but the number of layers of the metal wiring line 31 is not limited. Furthermore, a plurality of junction electrodes 33 is formed on the junction surface with the second semiconductor 12 which is a lower surface of the wiring layer 41. The junction electrode 33 is CuCu-bonded to a junction electrode 55 of the second semiconductor 12, and electrically connects the first semiconductor 11 and the second semiconductor 12. As a material of the metal wiring line 31 and the junction electrode 33, for example, copper (Cu), tungsten (W), aluminum (Al), gold (Au), or the like can be adopted. In the present embodiment, the metal wiring line 31 and the junction electrode 33 are formed containing copper. The insulating layer 32 is formed containing, for example, an SiO2 film, a low-k film (low dielectric constant insulating film), an SiOC film, or the like. The insulating layer 32 may include a plurality of insulating films containing different materials.

The first semiconductor 11 includes a plurality of pads 34 electrically connected to an external device by wire bonding or the like. Each pad 34 is formed containing, for example, aluminum, and is disposed on an outer peripheral portion, which is outside a pixel array unit in plan view. The pixel array unit is a region in which a plurality of pixels having the photodiodes 22 and the like formed is arranged in a matrix, and is formed in a central portion of the first semiconductor 11 in plan view. A through hole 35 penetrating the semiconductor substrate 21 and the planarizing film 23 is formed above the pad 34, and the through hole 35 exposes a part of an upper surface of the pad 34 on which a wire bond ball is formed.

Whereas, the second semiconductor 12 includes a semiconductor substrate 51 using, for example, silicon (Si) as a semiconductor, and a wiring layer 54 on a front surface side, which is the first semiconductor 11 side of the semiconductor substrate 51. The wiring layer 54 includes a plurality of layers of metal wiring lines 52 and an insulating layer 53. In the example of FIG. 1, the number of layers of the metal wiring lines 52 is 4, but the number of layers of the metal wiring line 52 is not limited. A plurality of MOS transistors Tr1 is formed on an interface of a front surface of the semiconductor substrate 51. The plurality of MOS transistors Tr1 is separated by an element separating unit 57 of shallow trench isolation (STI) or the like. Furthermore, a plurality of junction electrodes 55 is formed on the junction surface with the first semiconductor 11, which is an upper surface of the wiring layer 54. The junction electrode 55 is CuCu-bonded to the junction electrode 33 of the first semiconductor 11, to electrically connect the first semiconductor 11 and the second semiconductor 12. Each of the junction electrodes 55 is individually connected to the uppermost metal wiring line 52 in a region that is not illustrated. In the semiconductor substrate 51, a through electrode (through silicon via) 56 penetrating the substrate is formed, and the wiring layer 54 of the second semiconductor 12 and a wiring layer 64 of the third semiconductor 13 are electrically connected via the through electrode 56. As a material of the metal wiring line 52 and the junction electrode 55, for example, copper (Cu), tungsten (W), aluminum (Al), gold (Au), or the like can be adopted. In the present embodiment, the metal wiring line 52 and the junction electrode 55 are formed containing copper. The insulating layer 53 is formed containing, for example, an SiO2 film, a low-k film (low dielectric constant insulating film), an SiOC film, or the like. The insulating layer 53 may include a plurality of insulating films containing different materials.

In the second semiconductor 12, the conversion circuit 81 that converts an electrical characteristic or a physical characteristic is formed in order to make the electrical characteristic or the physical characteristic compatible with the third semiconductor 13.

The third semiconductor 13 includes a semiconductor substrate 61 using, for example, silicon (Si) as a semiconductor, and the wiring layer 64 on the front surface side of the semiconductor substrate 61, which is the second semiconductor 12 side. The wiring layer 64 includes a plurality of layers of metal wiring lines 62 and an insulating layer 63. In the example of FIG. 1, the number of layers of the metal wiring lines 62 is 3, but the number of layers of the metal wiring line 62 is not limited. Furthermore, a junction electrode 65 joined to the through electrode 56 of the second semiconductor 12 is formed on an upper surface of the wiring layer 64. The junction electrode 65 is connected to a predetermined metal wiring line 62 in a region that is not illustrated. A plurality of MOS transistors Tr2 is formed on an interface of the front surface of the semiconductor substrate 51. The plurality of MOS transistors Tr2 is separated by an element separating unit 66 of STI or the like. As a material of the metal wiring line 62 and the junction electrode 65, for example, copper (Cu), tungsten (W), aluminum (Al), gold (Au), or the like can be adopted. In the present embodiment, the metal wiring line 62 and the junction electrode 65 are formed containing copper. The insulating layer 63 is formed containing, for example, an SiO2 film, a low-k film (low dielectric constant insulating film), an SiOC film, or the like. The insulating layer 63 may include a plurality of insulating films containing different materials.

The support substrate 14 includes a semiconductor substrate using, for example, silicon (Si) as a semiconductor. The support substrate 14 is joined to the second semiconductor 12 and the third semiconductor 13 with the insulating layer 15 interposed in between. More specifically, outer sides of the second semiconductor 12 and the third semiconductor 13 are covered with an insulating film 16 formed at the time of joining the first semiconductor 11 to the third semiconductor 13, and the insulating layer 15 is embedded in a region where the second semiconductor 12 and the third semiconductor 13 are not stacked. The support substrate 14 is joined to the first semiconductor 11 with the insulating layer 15 interposed in between, in a region where neither the second semiconductor 12 nor the third semiconductor 13 is stacked.

As described above, the imaging device 1 of the first embodiment is configured by stacking the first semiconductor 11 to the third semiconductor 13 in the vertical direction. The second semiconductor 12 disposed between the first semiconductor 11 and the third semiconductor 13 includes the conversion circuit 81 that converts an electrical characteristic or a physical characteristic in accordance with the third semiconductor 13. As a result, a general-purpose semiconductor chip can be used as the third semiconductor 13, and the manufacturing cost is reduced.

A method of manufacturing the imaging device 1 will be briefly described.

The imaging device 1 is manufactured by a chip on wafer (CoW) technology in which the first semiconductor 11 in a wafer state is singulated after the second semiconductor 12 and the third semiconductor 13, which are singulated silicon dies, are joined and stacked on the first semiconductor 11 in a wafer state.

More specifically, on the semiconductor substrate 21 in a wafer state, the plurality of photodiodes 22 is formed in units of chip regions that are to be the first semiconductor 11, and the wiring layer 41 is formed on one surface of the semiconductor substrate 21. The one surface of the semiconductor substrate 21 on which the wiring layer 41 is formed is to be a front surface of the semiconductor substrate 21. Next, the second semiconductor 12 and the third semiconductor 13, which are manufactured and singulated in separate processes, are joined in units of chip regions of the first semiconductor 11 in a wafer state. In a region where the singulated second semiconductor 12 and third semiconductor 13 are not stacked, the insulating layer 15 is embedded, planarized, and then joined with the support substrate 14.

Next, after inversion such that the support substrate 14 in a wafer state is a lower surface and the semiconductor substrate 21 in a wafer state is an upper surface, the semiconductor substrate 21 in a wafer state is thinned until the photodiodes 22 formed in each chip region of the semiconductor substrate 21 are in the vicinity of an interface. Then, the planarizing film 23, the color filter 24, and the on-chip lens 25 are formed on the thinned semiconductor substrate 21.

Finally, the through hole 35 is formed at a position of the pad 34 on an outer peripheral portion of each chip region of the semiconductor substrate 21, and the upper surface of the pad 34 is exposed. As described above, the plurality of imaging devices 1 in a wafer state is completed and singulated in units of chips, whereby the state of the imaging device 1 in FIG. 1 is obtained.

### 2. Second Embodiment of Imaging Device

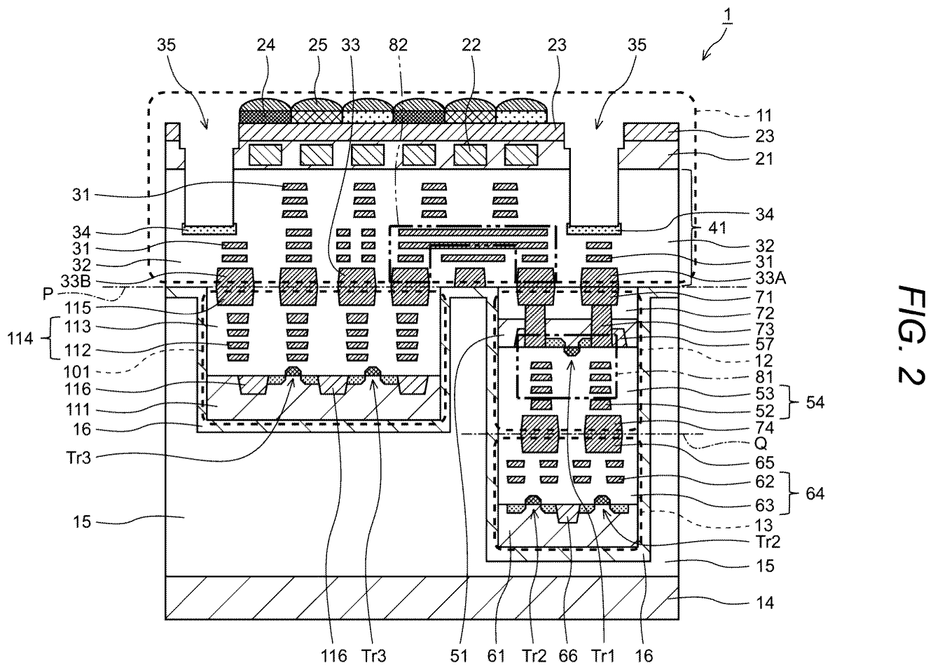

FIG. 2 illustrates a cross-sectional view of a second embodiment of an imaging device to which the present technology is applied.

In the second to fifth embodiments to be described with reference to FIGS. 2 to 5, the same reference numerals are given to the same parts as those of each embodiment described above, and the description of the parts will be omitted as appropriate, and the description will be given focusing on different parts.

An imaging device 1 according to the second embodiment illustrated in FIG. 2 is in common with the first embodiment illustrated in FIG. 1 in that the imaging device 1 is configured by stacking a first semiconductor 11 to a third semiconductor 13 in the vertical direction. Whereas, the imaging device 1 of the second embodiment is different from that of the first embodiment in that a fourth semiconductor 101 is also joined to the first semiconductor 11, in addition to the first semiconductor 11 to the third semiconductor 13. The fourth semiconductor 101 is joined to a planar region different from the region where a second semiconductor 12 is joined, in a junction surface of the first semiconductor 11 indicated by a one dotted chain line P. A junction electrode 33 of a wiring layer 41 of the first semiconductor 11 includes a junction electrode 33A joined to a junction electrode 71 of the second semiconductor 12 and a junction electrode 33B joined to a junction electrode 115 of the fourth semiconductor 101.

In the first embodiment of FIG. 1, the first semiconductor 11 and the second semiconductor 12 are joined with wiring layers thereof facing each other. However, in the second embodiment, a wiring layer 54 of the second semiconductor 12 is joined to face a wiring layer 64 of the third semiconductor 13. The junction electrode 71 and an insulating layer 72 are formed on a back surface side of a semiconductor substrate 51 of the second semiconductor 12, and the junction electrode 33A formed on the wiring layer 41 of the first semiconductor 11 is electrically connected by CuCu-bonding to the junction electrode 71 formed on the back surface side of the semiconductor substrate 51 of the second semiconductor 12. The junction electrode 71 is connected to a metal wiring line 52 of the wiring layer 54 on the front surface side via a through electrode 73 penetrating the semiconductor substrate 51.

A one dotted chain line Q indicates a junction surface between the second semiconductor 12 and the third semiconductor 13, and a junction electrode 74 of the wiring layer 54 of the second semiconductor 12 and a junction electrode 65 of the wiring layer 64 of the third semiconductor 13 are CuCu-bonded to electrically connect the second semiconductor 12 and the third semiconductor 13.

Whereas, the fourth semiconductor 101 includes a semiconductor substrate 111 using, for example, silicon (Si) as a semiconductor, and a wiring layer 114 on a front surface, which is the first semiconductor 11 side of the semiconductor substrate 111. The wiring layer 114 includes a plurality of layers of metal wiring lines 112 and an insulating layer 113. In the example of FIG. 2, the number of layers of the metal wiring lines 112 is 4, but the number of layers of the metal wiring line 112 is not limited. A plurality of junction electrodes 115 is formed on an uppermost layer of the wiring layer 114, and the junction electrode 115 is CuCu-bonded to the junction electrode 33B on the first semiconductor 11 side, to electrically connect the first semiconductor 11 and the fourth semiconductor 101. Each of the junction electrodes 115 is individually connected to the uppermost metal wiring line 112 in a region that is not illustrated.

A plurality of MOS transistors Tr3 is formed on an interface of the front surface of the semiconductor substrate 111. The plurality of MOS transistors Tr3 is separated by an element separating unit 116 of STI or the like. As a material of the metal wiring line 112 and the junction electrode 115, for example, copper (Cu), tungsten (W), aluminum (Al), gold (Au), or the like can be adopted. In the present embodiment, the metal wiring line 112 and the junction electrode 115 are formed containing copper. The insulating layer 113 is formed containing, for example, an SiO2 film, a low-k film (low dielectric constant insulating film), an SiOC film, or the like. The insulating layer 113 may include a plurality of insulating films containing different materials.

As described above, the imaging device 1 of the second embodiment is configured by stacking the first semiconductor 11 to the third semiconductor 13 in the vertical direction. Furthermore, in the first semiconductor 11, the fourth semiconductor 101 is joined to a region different from the second semiconductor 12. The first semiconductor 11 has a larger plane size than any of the second semiconductor 12, the third semiconductor 13, and the fourth semiconductor 101. One or more metal wiring lines 31 and junction electrodes 33 formed in a region 82 in the wiring layer 41 of the first semiconductor 11 are used to electrically connect the fourth semiconductor 101 and the second semiconductor 12. Since a conversion circuit 81 of the second semiconductor 12 is connected to the third semiconductor 13, the third semiconductor 13 is electrically connected to the fourth semiconductor 101 via the conversion circuit 81 of the second semiconductor 12 and the metal wiring line 31 in the region 82 of the first semiconductor 11. The conversion circuit 81 includes a circuit that converts an electrical characteristic or a physical characteristic between the fourth semiconductor 101 and the third semiconductor 13. As a result, a general-purpose semiconductor chip can be used for both the third semiconductor 13 and the fourth semiconductor 101, and the manufacturing cost can be further reduced.

One of the third semiconductor 13 and the fourth semiconductor 101 can be, for example, an AI chip mounted with an AI processing circuit that performs AI processing based on a signal generated in each pixel of the first semiconductor 11, and the other one can be a memory chip mounted with a memory circuit that stores a signal generated in each pixel of the first semiconductor 11 and the like.

The imaging device 1 of the second embodiment can be manufactured, for example, by manufacturing a chip (silicon die) stacked by joining the second semiconductor 12 and the third semiconductor 13 and a chip (silicon die) of the fourth semiconductor 101 in separate processes, and joining the chips to the first semiconductor 11 in a wafer state.

### 3. Third Embodiment of Imaging Device

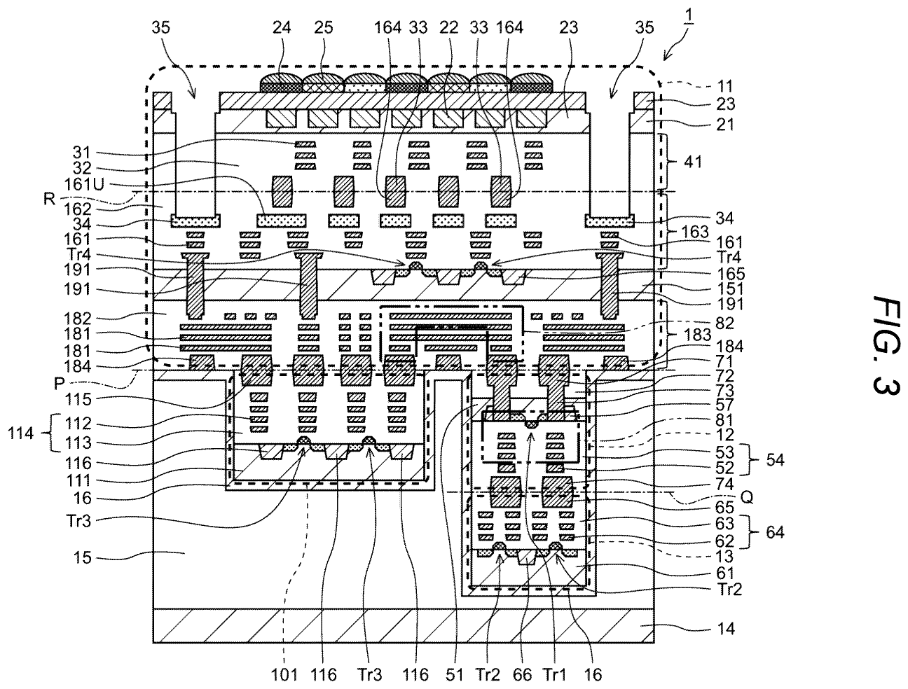

FIG. 3 illustrates a cross-sectional view of a third embodiment of an imaging device to which the present technology is applied.

In the first and second embodiments described above, the first semiconductor 11 has a structure including one semiconductor substrate 21. However, in the third embodiment illustrated in FIG. 3, a first semiconductor 11 has a stacked structure of two semiconductor substrates.

Specifically, the first semiconductor 11 of an imaging device 1 according to the third embodiment in FIG. 3 is configured by stacking a semiconductor substrate 21 and a semiconductor substrate 151. In the semiconductor substrate 21 and the semiconductor substrate 151, the semiconductor substrate 21 is disposed on a light incident surface side which is an upper side in the figure, and the semiconductor substrate 151 is disposed on a side close to a second semiconductor 12 and a fourth semiconductor 101.

In the semiconductor substrate 21, similarly to the first and second embodiments, photodiodes 22 are formed in pixel units, and a color filter 24, an on-chip lens 25, and the like are formed on a back surface serving as the light incident surface in the semiconductor substrate 21. A wiring layer 41 is formed on the front surface side of semiconductor substrate 21, which is also similar to the first and second embodiments.

Whereas, a wiring layer 163 including a plurality of layers of metal wiring lines 161 and an insulating layer 162 is formed on the semiconductor substrate 21 side which is the front surface side of the semiconductor substrate 151. In the example of FIG. 3, the number of layers of the metal wiring lines 161 is 4, but the number of layers of the metal wiring line 161 is not limited. Among the plurality of layers of the metal wiring lines 161, a part of an uppermost metal wiring line 161U constitutes a pad 34. As a material of the metal wiring line 161, for example, copper (Cu), tungsten (W), aluminum (Al), gold (Au), or the like can be adopted. However, for example, aluminum is used as a material of the uppermost metal wiring line 1610 partially used as the pad 34, and for example, copper is used for the other metal wiring lines 161.

Furthermore, a plurality of junction electrodes 164 is formed on an upper surface of the wiring layer 163. As a material of the junction electrode 164, for example, copper (Cu), tungsten (W), aluminum (Al), gold (Au), or the like can be adopted, but the junction electrode 164 is formed containing copper in the present embodiment. Each junction electrode 164 of the wiring layer 163 is connected by CuCu-bonding to a junction electrode 33 of the wiring layer 41 of the semiconductor substrate 21. A one dotted chain line R indicates a junction surface between the wiring layer 41 on the semiconductor substrate 21 side and the wiring layer 163 on the semiconductor substrate 151 side.

On the back surface side (lower side in the figure) of the semiconductor substrate 151, a wiring layer 183 including a plurality of layers of metal wiring lines 181 and an insulating layer 182 is formed. The plurality of layers of the metal wiring lines 181 is formed by rewiring (RDL). In the example of FIG. 3, the number of layers of the metal wiring lines 181 is 4, but the number of layers of the metal wiring line 181 is not limited. Furthermore, on a junction surface between the wiring layer 183 and the second semiconductor 12 and the fourth semiconductor 101 indicated by a one dotted chain line P, a plurality of junction electrodes 184 is formed. In the junction surface, some of the junction electrodes 184 are CuCu-bonded to a junction electrode 71 of the second semiconductor 12, to electrically connect the first semiconductor 11 and the second semiconductor 12. Other junction electrodes 184 are CuCu-bonded to a junction electrode 115 of the fourth semiconductor 101, to electrically connect the first semiconductor 11 and the fourth semiconductor 101. As a material of the metal wiring line 181 and the junction electrode 184, for example, copper (Cu), tungsten (W), aluminum (Al), gold (Au), or the like can be adopted, but the metal wiring line 181 and the junction electrode 184 are formed containing copper in the present embodiment. The insulating layers 162 and 182 are formed containing, for example, an SiO2 film, a low-k film (low dielectric constant insulating film), an SiOC film, or the like. The insulating layers 162 and 182 may include a plurality of insulating films containing different materials.

A plurality of MOS transistors Tr4 is formed at an interface on the front surface side of the semiconductor substrate 151. The plurality of MOS transistors Tr4 is separated by an element separating unit 165 of STI or the like.

A plurality of through electrodes 191 penetrating the substrate is formed on the semiconductor substrate 151, and the wiring layer 163 on the front surface side and the wiring layer 183 on the back surface side are electrically connected via the through electrodes 191.

As described above, in the imaging device 1 of the third embodiment, the second semiconductor 12 and the third semiconductor 13 stacked in the vertical direction are joined to the first semiconductor 11, and the fourth semiconductor 101 is joined to a region different from the second semiconductor 12. Furthermore, in addition, the first semiconductor 11 has a stacked structure of the semiconductor substrate 21 and the semiconductor substrate 151. Among the plurality of layers of metal wiring lines 181 formed by rewiring on the back surface side of the semiconductor substrate 151, one or more metal wiring lines 181 and junction electrodes 184 in a region 82 are used to electrically connect the fourth semiconductor 101 and the second semiconductor 12. Since a conversion circuit 81 of the second semiconductor 12 is electrically connected to the third semiconductor 13, the third semiconductor 13 is electrically connected to the fourth semiconductor 101 via the conversion circuit 81 of the second semiconductor 12 and a metal wiring line 31 in the region 82 of the first semiconductor 11. The conversion circuit 81 includes a circuit that converts an electrical characteristic or a physical characteristic between the fourth semiconductor 101 and the third semiconductor 13. As a result, since general-purpose semiconductor chips can be used for both the third semiconductor 13 and the fourth semiconductor 101, the manufacturing cost can be further reduced.

According to the third embodiment, since the first semiconductor 11 has a stacked structure of the semiconductor substrate 21 and the semiconductor substrate 151, a circuit area of the first semiconductor 11 can be increased as compared with the first and second embodiments. For example, an analog processing circuit before conversion of a pixel signal output from each pixel arranged in a matrix into a digital signal can be formed in the first semiconductor 11.

### 4. Fourth Embodiment of Imaging Device

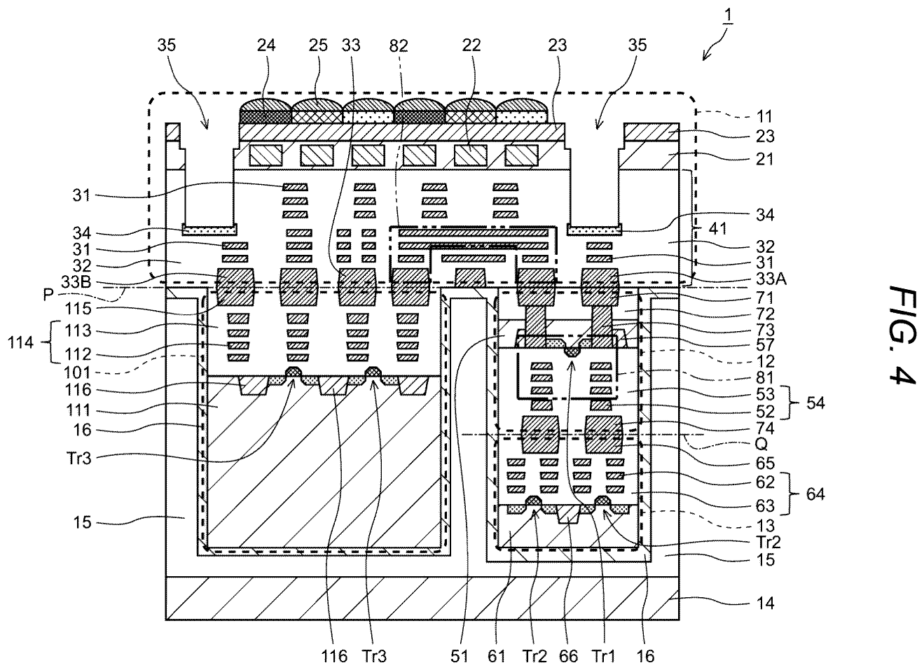

FIG. 4 illustrates a cross-sectional view of a fourth embodiment of an imaging device to which the present technology is applied.

An imaging device 1 according to the fourth embodiment illustrated in FIG. 4 is in common with the second embodiment illustrated in FIG. 2 in that a second semiconductor 12 and a third semiconductor 13 stacked in a vertical direction are joined to a part of a planar region of a first semiconductor 11, and a fourth semiconductor 101 is joined to a planar region of the first semiconductor 11 different from the second semiconductor 12.

Whereas, the fourth embodiment in FIG. 4 is different from the second embodiment in that a thickness of the second semiconductor 12 and the third semiconductor 13 is the same as a thickness of the fourth semiconductor 101, as compared with the second embodiment illustrated in FIG. 2 in which a thickness of the stacked second semiconductor 12 and third semiconductor 13 is different from a thickness of the fourth semiconductor 101. In other words, in the imaging device 1 of the fourth embodiment, a thickness of a semiconductor substrate 111 is formed to be thick so that the thickness of the fourth semiconductor 101 is the same as the thickness of the second semiconductor 12 and the third semiconductor 13. The imaging device 1 of the fourth embodiment is configured similarly to the second embodiment except for the thickness of the semiconductor substrate 111.

Similarly to the second embodiment, the imaging device 1 of the fourth embodiment can be manufactured, for example, by manufacturing a chip stacked by joining the second semiconductor 12 and the third semiconductor 13 and a chip of the fourth semiconductor 101 in separate processes, and joining the chips to the first semiconductor 11 in a wafer state. By making a thickness of the chip of the fourth semiconductor 101 equal to a thickness of the chip obtained by joining the second semiconductor 12 and the third semiconductor 13, a process of joining to the first semiconductor 11 in a wafer state is facilitated.

Note that, in the fourth embodiment illustrated in FIG. 4, the first semiconductor 11 has a single-layer structure using one semiconductor substrate 21 similarly to the second embodiment, but may have a stacked structure in which a semiconductor substrate 21 and a semiconductor substrate 151 are stacked similarly to the third embodiment in FIG. 3.

### 5. Fifth Embodiment of Imaging Device

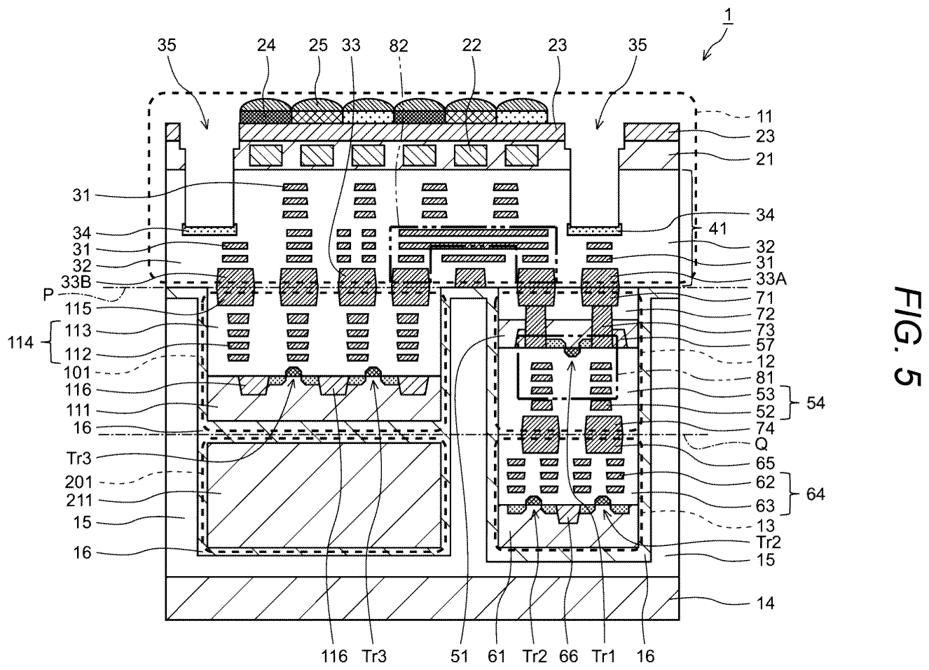

FIG. 5 illustrates a cross-sectional view of a fifth embodiment of an imaging device to which the present technology is applied.

An imaging device 1 according to the fifth embodiment illustrated in FIG. 5 is in common with the second embodiment illustrated in FIG. 2 in that a second semiconductor 12 and a third semiconductor 13 stacked in a vertical direction are joined to a part of a planar region of a first semiconductor 11, and a fourth semiconductor 101 is joined to a planar region of the first semiconductor 11 different from the second semiconductor 12.

Whereas, the fifth embodiment in FIG. 5 is different from the second embodiment in that a fifth semiconductor 201 including only a semiconductor substrate 211 is further stacked on a lower side (support substrate 14 side) of the fourth semiconductor 101. In the fifth embodiment of FIG. 5, the fifth semiconductor 201 is stacked on the lower side of the fourth semiconductor 101, so that a total thickness of the fourth semiconductor 101 and the fifth semiconductor 201 is formed to be the same as a total thickness of the second semiconductor 12 and the third semiconductor 13. In other words, in the imaging device 1 of the fifth embodiment, the fifth semiconductor 201 is added such that a combined thickness of the fourth semiconductor 101 and the fifth semiconductor 201 is the same as a combined thickness of the second semiconductor 12 and the third semiconductor 13. The semiconductor substrate 211 constituting the fifth semiconductor 201 is a dummy substrate on which no circuit or the like is formed. The outside of the semiconductor substrate 211 is covered with an insulating film 16, and the semiconductor substrate 111 of the fourth semiconductor 101 and the semiconductor substrate 211 of the fifth semiconductor 201 are connected by oxide film joining of the insulating film 16. The fourth embodiment is configured similarly to the second embodiment except that the fifth semiconductor 201 is added.

Similarly to the second embodiment, for example, the imaging device 1 of the fifth embodiment can be manufactured by manufacturing a chip stacked by joining the second semiconductor 12 and the third semiconductor 13, and a chip stacked by joining the fourth semiconductor 101 and the fifth semiconductor 201 formed so as to be aligned with the thickness of the chip in separate processes, and joining the chips to the first semiconductor 11 in a wafer state. By adjusting the thickness of the joined chip of the fourth semiconductor 101 and the fifth semiconductor 201 to the thickness of the joined chip of the second semiconductor 12 and the third semiconductor 13, a process of joining to the first semiconductor 11 in a wafer state is facilitated.

Note that, in the fifth embodiment illustrated in FIG. 5, the first semiconductor 11 has a single-layer structure using one semiconductor substrate 21 similarly to the second embodiment, but may have a stacked structure in which the semiconductor substrate 21 and the semiconductor substrate 151 are stacked similarly to the third embodiment in FIG. 3.

### <6. Block Diagram of Imaging Device>

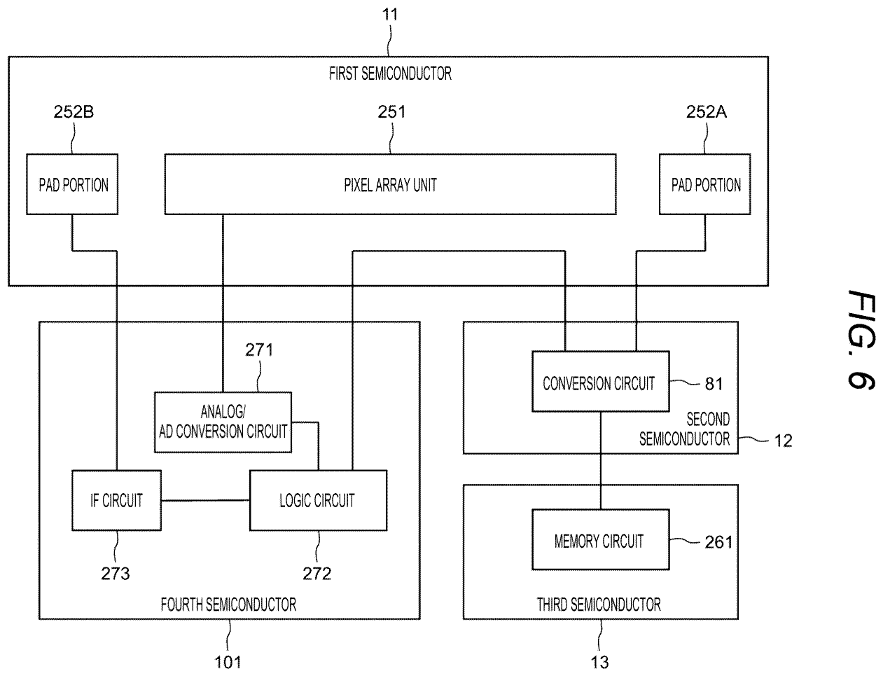

FIG. 6 is a block diagram illustrating a configuration example of an imaging device 1 in a case where the imaging device 1 includes a first semiconductor to a fourth semiconductor similarly to the second to fifth embodiments described above.

A first semiconductor 11 includes a pixel array unit 251 in which a plurality of pixels having photodiodes 22 and the like formed are arranged in a matrix, and pad portions 252A and 252B. The pad portions 252A and 252B include the plurality of pads 34 illustrated in FIG. 1, and correspond to input/output units of the imaging device 1. The pad portion 252A includes the plurality of pads 34 electrically connected to a second semiconductor 12, and the pad portion 252B includes the plurality of pads 34 electrically connected to a fourth semiconductor 101.

The second semiconductor 12 includes at least a conversion circuit 81. The conversion circuit 81 converts an electrical characteristic or a physical characteristic between the first semiconductor 11 and a third semiconductor 13, and converts an electrical characteristic or a physical characteristic between the third semiconductor 13 and the fourth semiconductor 101. By providing the second semiconductor 12 including at least the conversion circuit 81, compatibility with the third semiconductor 13 to be joined can be improved.

The third semiconductor 13 includes a memory circuit 261 including, for example, a frame memory. The memory circuit 261 stores data supplied from a logic circuit 272 of the fourth semiconductor 101 via the conversion circuit 81.

The fourth semiconductor 101 includes an analog/AD conversion circuit 271, the logic circuit 272, and an IF circuit 273. The analog/AD conversion circuit 271 includes an analog signal processing circuit that processes an analog signal output from each pixel of the pixel array unit 251 and an AD conversion circuit that converts an analog signal into a digital signal. The analog/AD conversion circuit 271 outputs the signal converted (AD-converted) to digital to the logic circuit 272. The logic circuit 272 performs various kinds of digital signal processing such as, for example, black level adjustment and column variation correction, on a signal supplied from the analog/AD conversion circuit 271. The logic circuit 272 outputs the processed signal to the IF circuit 273, and causes the processed signal to be stored in the memory circuit 261 of the third semiconductor 13 as necessary. The IF circuit 273 converts the signal supplied from the logic circuit 272 into a predetermined format such as a mobile industry processor interface (MIPI) standard, for example, and outputs the signal to an external device via the pad portion 252B.

In a case where the imaging device 1 includes the first semiconductor to the fourth semiconductor, the logic circuit 272 may be provided in the third semiconductor 13, and the memory circuit 261 may be provided in the fourth semiconductor. Alternatively, one or both of the memory circuit 261 and the logic circuit 272 may be provided in both the third semiconductor 13 and the fourth semiconductor. The logic circuit 272 includes a signal processing circuit that processes a signal generated in each pixel and an AI processing circuit that performs AI processing based on the signal generated in each pixel.

### <7. Specific Configuration Example of Conversion Circuit>

Next, a specific configuration example of the conversion circuit 81 provided in the second semiconductor 12 will be described.

### <Parallel-Serial Conversion Circuit>

The conversion circuit 81 can include, for example, a parallel-serial conversion circuit. The parallel-serial conversion circuit is an example of a conversion circuit that converts an electrical characteristic between the first semiconductor 11 and the third semiconductor 13.

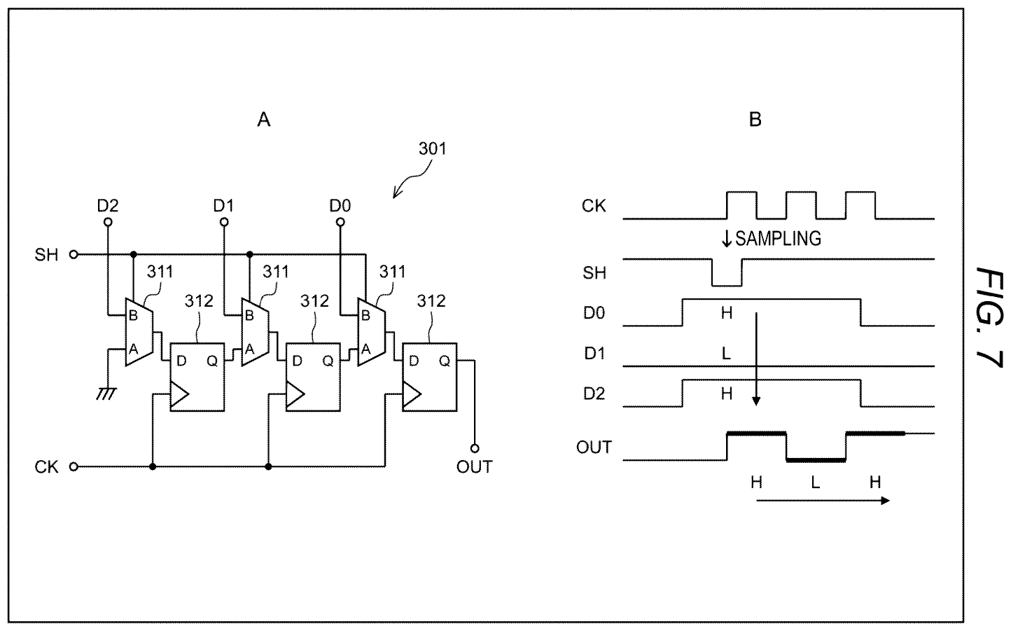

FIG. 7 illustrates a specific configuration example and a timing chart of the parallel-serial conversion circuit included in the conversion circuit 81.

A parallel-serial conversion circuit 301 includes three selectors 311 and D flip-flops 312, and converts three parallel signals D0, D1, and D2 into serial signals and outputs the serial signals. One of the parallel signals D0, D1, and D2 and an SH signal for controlling a sampling timing are input to each selector 311. Each selector 311 outputs the signal D0, D1, or D2 of an input B when the SH signal is Low. At rising of a clock signal CK, each D flip-flop 312 stores the signal output from the selector 311 in the previous stage and supplied to an input D, and outputs the signal from an output Q. As a result, the signals D0, D1, and D2 are sequentially output from an output OUT of the parallel-serial conversion circuit 301. The parallel-serial conversion circuit 301 can convert a low-speed parallel signal into a high-speed serial signal and output the serial signal.

### <Serial-Parallel Conversion Circuit>

The conversion circuit 81 can include, for example, a serial-parallel conversion circuit. The serial-parallel conversion circuit is an example of a conversion circuit that converts an electrical characteristic between the first semiconductor 11 and the third semiconductor 13.

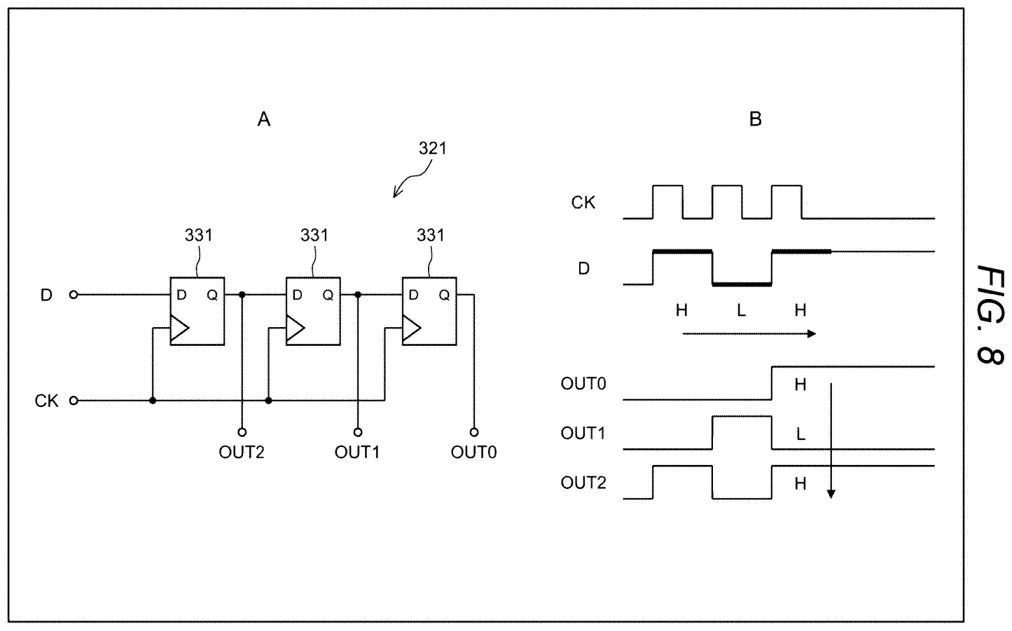

FIG. 8 illustrates a specific configuration example and a timing chart of the serial-parallel conversion circuit included in the conversion circuit 81.

A serial-parallel conversion circuit 321 is configured by connecting three D flip-flops 331, and converts three sequentially input signals D0, D1, and D2 into parallel signals and outputs the parallel signals. At rising of a clock signal CK, each D flip-flop 331 stores a signal supplied to an input D, and outputs the signal from the output Q. As a result, the signals D0, D1, and D2 are simultaneously output from outputs OUT0, OUT1, and OUT2 of the serial-parallel conversion circuit 321. The serial-parallel conversion circuit 321 can convert a high-speed serial signal into a low-speed parallel signal and output the parallel signal.

In a case where general-purpose semiconductor chips are used as the third semiconductor 13 and the fourth semiconductor 101, the number of parallels is limited by the number of pads of the semiconductor chip. By providing the parallel-serial conversion circuit 301 or the serial-parallel conversion circuit 321 as at least a part of the conversion circuit 81, it is possible to increase the number of parallels of data signals and increase a data rate.

### <Wiring Pitch Conversion Unit>

For example, in a case where a general-purpose semiconductor chip is used as the third semiconductor 13 on which the memory circuit 261 (FIG. 6) is formed, it is conceivable that a wiring pitch of the third semiconductor 13 and a wiring pitch of the first semiconductor 11 are different from each other. For example, the wiring pitch of the third semiconductor 13 using the general-purpose semiconductor chip is larger (wider) than the wiring pitch of the first semiconductor 11. The conversion circuit 81 may include a wiring pitch conversion unit that converts a wiring pitch between the first semiconductor 11 and the third semiconductor 13. The wiring pitch conversion unit is an example of a conversion circuit that converts a physical characteristic between the first semiconductor 11 and the third semiconductor 13. By providing the wiring pitch conversion unit, compatibility with the third semiconductor 13 to be joined can be improved.

### <Logic Circuit Unit>

The conversion circuit 81 can include, for example, a logic circuit unit such as an arithmetic operation circuit that performs arithmetic operations on a plurality of images stored in the memory circuit 261, arithmetic operations on a plurality of pixels in an image, and the like, and a clock generation circuit that generates the clock signal CK, such as the above-described serial-parallel conversion circuit. The logic circuit unit is an example of a conversion circuit that converts an electrical characteristic between the first semiconductor 11 and the third semiconductor 13. By providing the logic circuit unit, a circuit area of the first semiconductor 11 can be reduced.

### <Format Conversion Unit>

The conversion circuit 81 can include, for example, a format conversion unit. The format conversion unit is, for example, a circuit that converts a signal format into a signal format conforming to a standard such as DDR4, DDR5, or MIPI and outputs a signal in the converted signal format. The format conversion unit is an example of a conversion circuit that converts an electrical characteristic between the first semiconductor 11 and the third semiconductor 13. By providing the format conversion unit, the signal format can be converted, and a degree of freedom of a communication method can be improved.

### <Power Supply Unit>

The conversion circuit 81 can include, for example, a power supply unit. The power supply unit is, for example, a circuit that supplies a power supply voltage input from the pad portion 252A or 252B to the third semiconductor 13. The power supply unit is an example of a conversion circuit that converts an electrical characteristic between the first semiconductor 11 and the third semiconductor 13.

### <Test Circuit>

The conversion circuit 81 can include, for example, a test circuit that tests an operation of the third semiconductor 13. For example, in a case where the analog/AD conversion circuit 271 or the logic circuit 272 is provided in the third semiconductor 13, the test circuit is a circuit for testing operations of these circuits. The test circuit is an example of a conversion circuit that converts an electrical characteristic between the first semiconductor 11 and the third semiconductor 13.

### 8. Summary

In the imaging device 1, the first semiconductor 11, the second semiconductor 12, and the third semiconductor 13 are stacked in a vertical direction, and the second semiconductor 12 disposed between the first semiconductor 11 and the third semiconductor 13 includes the conversion circuit 81 that converts an electrical characteristic or a physical characteristic. By providing the conversion circuit 81 in the second semiconductor 12, a general-purpose semiconductor chip can be adopted as the third semiconductor 13, and manufacturing cost of the imaging device 1 can be reduced. In a case where the fourth semiconductor 101 is also joined, a general-purpose semiconductor chip can also be adopted as the fourth semiconductor 101, and the manufacturing cost of the imaging device 1 can be further reduced. The first semiconductor 11 is formed with a plane size larger than any of the second semiconductor 12, the third semiconductor 13, and the fourth semiconductor 101, and the second semiconductor 12 and the fourth semiconductor 101 are disposed in different planar regions of the first semiconductor 11.

### 9. Usage Example of Imaging Device

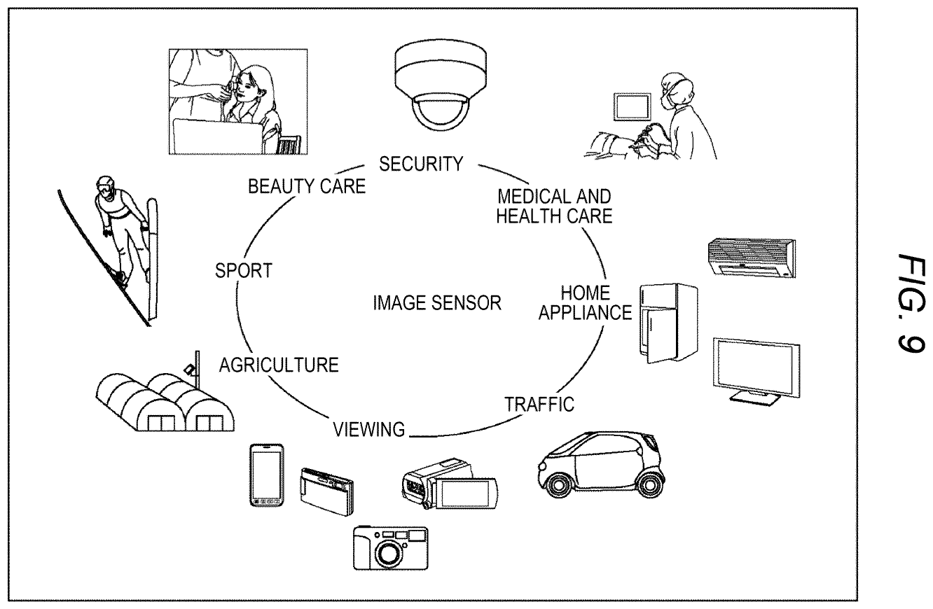

FIG. 9 is a diagram illustrating a usage example of an image sensor using the above-described imaging device 1.

The above-described imaging device 1 can be used as an image sensor, for example, in various cases of sensing light such as visible light, infrared light, ultraviolet light, and X-rays as described below.
A device that captures an image to be used for viewing, such as a digital camera and a portable device with a camera function
A device for traffic purpose such as an in-vehicle sensor that captures images of the front, rear, surroundings, interior, and the like of an automobile, a monitoring camera for monitoring traveling vehicles and roads, and a ranging sensor that measures a distance between vehicles and the like for safe driving such as automatic stop, recognition of a driver's condition, and the like
A device for home appliance such as a television, a refrigerator, and an air conditioner that captures an image of a user's gesture and performs a device operation according to the gesture
A device used for medical and health care such as an endoscope and a device that performs angiography by receiving infrared light
A device used for security such as a security monitoring camera and an individual authentication camera
A device used for beauty care such as a skin measuring instrument for capturing images of skin and a microscope for capturing images of the scalp
A device used for sport such as an action camera or a wearable camera for sports applications or the like
A device used for agriculture such as a camera for monitoring conditions of fields and crops.

### 10. Example of Application to Electronic Apparatus

The present technology is not limited to application to an imaging device. That is, the present technology can be applied to general electronic apparatuses that use an imaging device as an image capturing unit (photoelectric conversion element), such as an imaging device such as a digital still camera or a video camera, a mobile terminal device having an imaging function, and a copying machine using an imaging device for an image reading unit. The imaging device may be formed as one chip, or may be in a module form having an imaging function in which an imaging section and a signal processing unit or an optical system are packaged together.

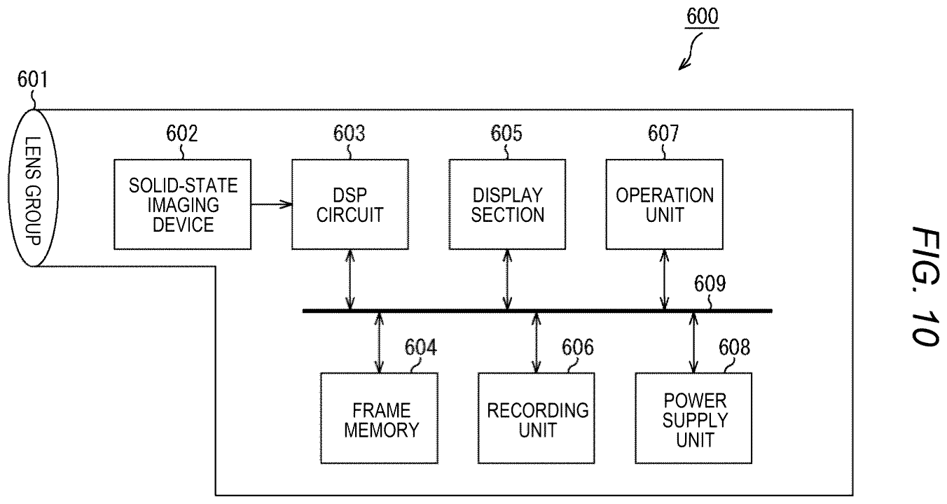

FIG. 10 is a block diagram illustrating a configuration example of an electronic apparatus to which the present technology is applied.

An electronic apparatus 600 in FIG. 10 includes an optical unit 601 including a lens group and the like, a solid-state imaging device (imaging device) 602 that adopts the configuration of the imaging device 1 in FIG. 1, and a digital signal processor (DSP) circuit 603 that is a camera signal processing circuit. Furthermore, the electronic apparatus 600 also includes a frame memory 604, a display section 605, a recording unit 606, an operation unit 607, and a power supply unit 608. The DSP circuit 603, the frame memory 604, the display section 605, the recording unit 606, the operation unit 607, and the power supply unit 608 are connected with each other via a bus line 609.

The optical unit 601 captures incident light (image light) from a subject and forms an image on an imaging surface of the solid-state imaging device 602. The solid-state imaging device 602 converts the light amount of the incident light imaged on the imaging surface by the optical unit 601 into an electric signal in pixel units and outputs the electric signal as a pixel signal. As the solid-state imaging device 602, it is possible to use the imaging device 1 of FIG. 1, that is, an imaging device configured by joining, in a vertical direction, the first semiconductor 11 as a main substrate and the second semiconductor 12 and the third semiconductor 13 which are silicon dies smaller in plane size than the first semiconductor, in which the conversion circuit 81 is provided in the second semiconductor 12 disposed between the first semiconductor 11 and the third semiconductor 13.

The display section 605 includes, for example, a thin display such as a liquid crystal display (LCD) or an organic electro luminescence (EL) display, and displays a moving image or a still image captured by the solid-state imaging device 602. The recording unit 606 records the moving image or the still image captured by the solid-state imaging device 602 on a recording medium such as a hard disk or a semiconductor memory.

The operation unit 607 issues operation commands for various functions of the electronic apparatus 600 under operation by a user. The power supply unit 608 supplies various power sources serving as operation power sources for the DSP circuit 603, the frame memory 604, the display section 605, the recording unit 606, and the operation unit 607 to these supply targets as appropriate.

As described above, by using the imaging device 1 to which any of the above-described embodiments is applied as the solid-state imaging device 602, the manufacturing cost can be reduced and a yield can be improved. Therefore, even in the electronic apparatus 600 such as a video camera, a digital still camera, and a camera module for a mobile device such as a mobile phone, the manufacturing cost can be reduced and a yield can be improved.

### <11. Example Applications to Mobile Object>

The technology according to the present disclosure (the present technology) can be applied to various products. For example, the technology according to the present disclosure may be achieved in the form of a device to be mounted on a mobile object of any kind, such as an automobile, an electric vehicle, a hybrid electric vehicle, a motorcycle, a bicycle, a personal mobility, an airplane, a drone, a vessel, or a robot.

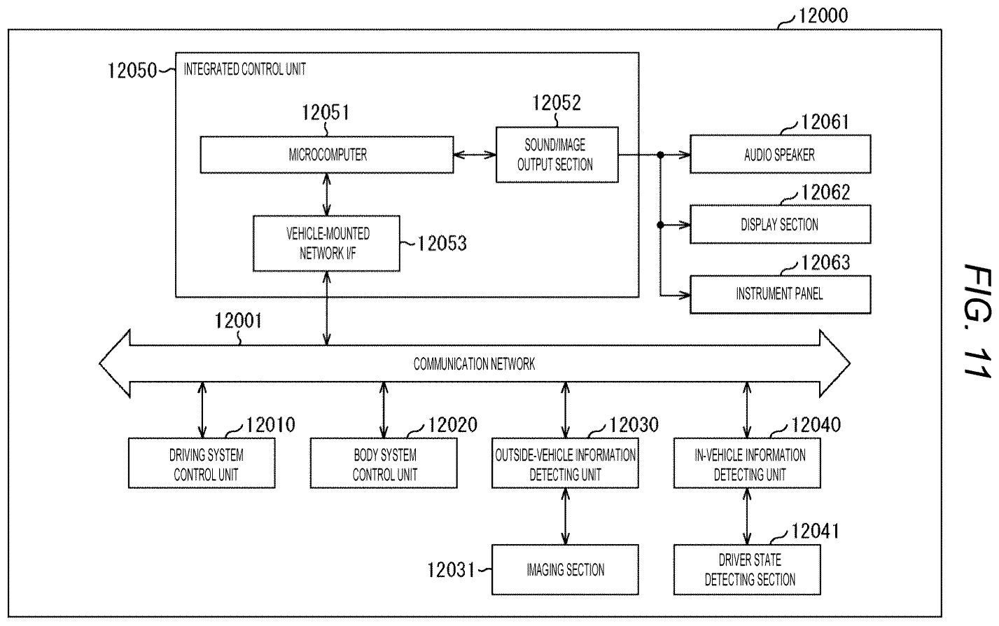

FIG. 11 is a block diagram illustrating an example of schematic configuration of a vehicle control system as an example of a mobile object control system to which the technology according to the present disclosure can be applied.

The vehicle control system 12000 includes a plurality of electronic control units connected to each other via a communication network 12001. In the example illustrated in FIG. 11, the vehicle control system 12000 includes a driving system control unit 12010, a body system control unit 12020, an outside-vehicle information detecting unit 12030, an in-vehicle information detecting unit 12040, and an integrated control unit 12050. Furthermore, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

Furthermore, the microcomputer 12051 can output a control command to the body system control unit 12020 on the basis of the information about the outside of the vehicle acquired by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 11, an audio speaker 12061, a display section 12062, and an instrument panel 12063 are illustrated as the output device. The display section 12062 may, for example, include at least one of an on-board display and a head-up display.

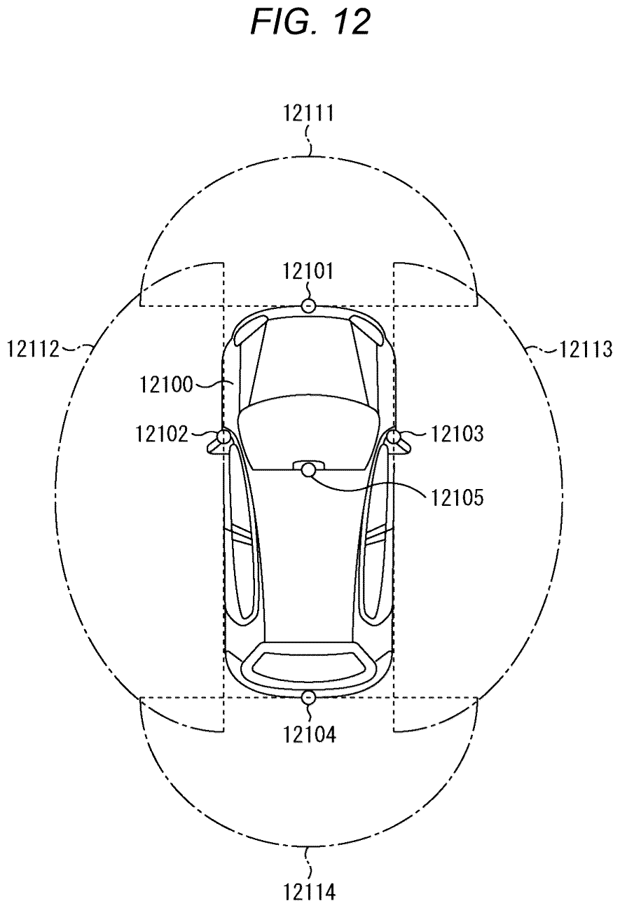

FIG. 12 is a diagram illustrating an example of the installation position of the imaging section 12031. In FIG. 12, a vehicle 12100 includes imaging sections 12101, 12102, 12103, 12104, and 12105, as the imaging section 12031.

The imaging sections 12101, 12102, 12103, 12104, 12105 are provided, for example, at positions such as a front nose, a sideview mirror, a rear bumper, a back door, and an upper portion of a windshield in the interior of the vehicle 12100. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The forward images obtained by the imaging sections 12101 and 12105 are used mainly to detect a preceding vehicle, a pedestrian, an obstacle, a traffic signal, a traffic sign, a lane, or the like.

Note that, FIG. 12 illustrates an example of photographing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

An example of the vehicle control system to which the technology according to the present disclosure can be applied has been described above. The technology according to the present disclosure can be applied to the imaging section 12031 among the configurations described above. Specifically, the imaging device 1 according to each of the above-described embodiments can be applied as the imaging section 12031. By applying the technology according to the present disclosure to the imaging section 12031, it is possible to obtain a more easily viewable captured image and acquire distance information, while reducing manufacturing cost and downsizing. Furthermore, it is possible to reduce driver's fatigue and increase the safety of the driver and the vehicle by using the obtained captured image and distance information.

Furthermore, the present disclosure is not limited to application to a solid-state imaging device that detects distribution of the amount of incident light of visible light and captures the distribution as an image, and can be applied to all solid-state imaging devices (physical quantity distribution detection devices) such as a solid-state imaging device that captures distribution of the amount of incident infrared rays, X-rays, particles, or the like as an image, and a fingerprint detection sensor that detects distribution of other physical quantities such as pressure and capacitance and captures the distribution as an image in a broad sense.

Furthermore, the present technology can be applied not only to solid-state imaging devices but also to general semiconductor devices having other semiconductor integrated circuits.

The embodiment of the present disclosure is not limited to the above-described embodiments and various modifications may be made without departing from the gist of the technique of the present disclosure.

For example, it is possible to adopt a mode obtained by combining all or some of the plurality of embodiments described above.

Note that, the effects described in the present specification are merely examples and are not limited, and there may be effects other than those described in the present specification.

Note that the technique of the present disclosure can have the following configurations.

(1)

A semiconductor device including
a first semiconductor, a second semiconductor, and a third semiconductor stacked in a vertical direction, in which
the second semiconductor disposed between the first semiconductor and the third semiconductor includes a conversion circuit that converts an electrical characteristic or a physical characteristic.
   (2)

The semiconductor device according to (1) above, in which
a fourth semiconductor is further joined to the first semiconductor in a planar region different from the second semiconductor.
   (3)

The semiconductor device according to (2) above, in which
the third semiconductor is connected to the fourth semiconductor via the conversion circuit of the second semiconductor and wiring of the first semiconductor.
   (4)

The semiconductor device according to (2) or (3) above, in which
the first semiconductor is formed by stacking a plurality of semiconductor substrates, and
the third semiconductor is connected to the fourth semiconductor via the conversion circuit of the second semiconductor and rewiring of the first semiconductor.
   (5)

The semiconductor device according to any one of (2) to (4) above, in which
the fourth semiconductor has a thickness different from a thickness of a stack of the second semiconductor and the third semiconductor.
   (6)

The semiconductor device according to any one of (2) to (4) above, in which
the fourth semiconductor has a thickness equal to a thickness of a stack of the second semiconductor and the third semiconductor.
   (7)

The semiconductor device according to (6) above, in which
a total thickness of the fourth semiconductor and a dummy substrate is equal to a thickness of a stack of the second semiconductor and the third semiconductor.
   (8)

The semiconductor device according to any one of (1) to (7) above, in which
the conversion circuit includes a parallel-serial conversion circuit.
   (9)

The semiconductor device according to any one of (1) to (8) above, in which
the conversion circuit includes a serial-parallel conversion circuit.
   (10)

The semiconductor device according to any one of (1) to (9) above, in which
the conversion circuit includes a wiring pitch conversion unit that converts a wiring pitch.
   (11)

The semiconductor device according to any one of (1) to (10) above, in which
the conversion circuit includes a logic circuit unit.
   (12)

The semiconductor device according to any one of (1) to (11) above, in which
the conversion circuit includes a format conversion unit that converts a signal format.
   (13)

The semiconductor device according to any one of (1) to (12) above, in which
the conversion circuit includes a power supply unit that supplies a power supply voltage to the third semiconductor.
   (14)

The semiconductor device according to any one of (1) to (13) above, in which
the conversion circuit includes a test circuit for the third semiconductor.
   (15)

The semiconductor device according to any one of (1) to (14) above, in which
the first semiconductor has a larger plane size than a plane size of any of the second semiconductor and the third semiconductor.
   (16)

The semiconductor device according to any one of (1) to (15) above, in which
the first semiconductor includes photoelectric conversion elements arranged in a matrix.
   (17)

The semiconductor device according to any one of (1) to (16) above, in which
the third semiconductor includes a logic circuit including a signal processing circuit or an AI processing circuit.
   (18)

The semiconductor device according to any one of (1) to (17) above, in which
the third semiconductor includes a memory circuit.
   (19)

An electronic apparatus including
a semiconductor device including
a first semiconductor, a second semiconductor, and
a third semiconductor stacked in a vertical direction, in which
the second semiconductor disposed between the first semiconductor and the third semiconductor includes a conversion circuit that converts an electrical characteristic or a physical characteristic.

### REFERENCE SIGNS LIST

1 Imaging device
11 First semiconductor
12 Second semiconductor
13 Third semiconductor
14 Support substrate
15 Insulating layer
16 Insulating film
21 Semiconductor substrate
22 Photodiode
23 Planarizing film
24 Color filter
25 On-chip lens
31 Metal wiring line
34 Pad
41 Wiring layer
51 Semiconductor substrate
61 Semiconductor substrate
81 Conversion circuit
82 Region
101 Fourth semiconductor
201 Fifth semiconductor
301 Parallel-serial conversion circuit
321 Serial-parallel conversion circuit
600 Electronic apparatus
602 Solid-state imaging device

1. A semiconductor device comprising
a first semiconductor, a second semiconductor, and a third semiconductor stacked in a vertical direction, wherein
the second semiconductor disposed between the first semiconductor and the third semiconductor includes a conversion circuit that converts an electrical characteristic or a physical characteristic.

2. The semiconductor device according to claim 1, wherein
a fourth semiconductor is further joined to the first semiconductor in a planar region different from the second semiconductor.

3. The semiconductor device according to claim 2, wherein
the third semiconductor is connected to the fourth semiconductor via the conversion circuit of the second semiconductor and wiring of the first semiconductor.

4. The semiconductor device according to claim 2, wherein
the first semiconductor is formed by stacking a plurality of semiconductor substrates, and
the third semiconductor is connected to the fourth semiconductor via the conversion circuit of the second semiconductor and rewiring of the first semiconductor.

5. The semiconductor device according to claim 2, wherein
the fourth semiconductor has a thickness different from a thickness of a stack of the second semiconductor and the third semiconductor.

6. The semiconductor device according to claim 2, wherein
the fourth semiconductor has a thickness equal to a thickness of a stack of the second semiconductor and the third semiconductor.

7. The semiconductor device according to claim 6, wherein
a total thickness of the fourth semiconductor and a dummy substrate is equal to a thickness of a stack of the second semiconductor and the third semiconductor.

8. The semiconductor device according to claim 1, wherein
the conversion circuit includes a parallel-serial conversion circuit.

9. The semiconductor device according to claim 1, wherein
the conversion circuit includes a serial-parallel conversion circuit.

10. The semiconductor device according to claim 1, wherein
the conversion circuit includes a wiring pitch conversion unit that converts a wiring pitch.

11. The semiconductor device according to claim 1, wherein
the conversion circuit includes a logic circuit unit.

12. The semiconductor device according to claim 1, wherein
the conversion circuit includes a format conversion unit that converts a signal format.

13. The semiconductor device according to claim 1, wherein
the conversion circuit includes a power supply unit that supplies a power supply voltage to the third semiconductor.

14. The semiconductor device according to claim 1, wherein
the conversion circuit includes a test circuit for the third semiconductor.

15. The semiconductor device according to claim 1, wherein
the first semiconductor has a larger plane size than a plane size of any of the second semiconductor and the third semiconductor.

16. The semiconductor device according to claim 1, wherein
the first semiconductor includes photoelectric conversion elements arranged in a matrix.

17. The semiconductor device according to claim 1, wherein
the third semiconductor includes a logic circuit including a signal processing circuit or an AI processing circuit.

18. The semiconductor device according to claim 1, wherein
the third semiconductor includes a memory circuit.

19. An electronic apparatus comprising
a semiconductor device including
a first semiconductor, a second semiconductor, and a third semiconductor stacked in a vertical direction, wherein
the second semiconductor disposed between the first semiconductor and the third semiconductor includes a conversion circuit that converts an electrical characteristic or a physical characteristic.
